(19) United States
(12) Patent Application Publication
(10) Pub. No.: US 2025/0157533 A1
(43) Pub. Date: May 15, 2025

(54) VERTICALLY INTEGRATED NEURAL NETWORK COMPUTING SYSTEM AND ASSOCIATED SYSTEMS AND METHODS

(71) Applicant: Micron Technology, Inc., Boise, ID (US)

(72) Inventors: Lingming Yang, Meridian, ID (US); Raghukiran Sreeramaneni, Frisco, TX (US); Nevil N. Gajera, Meridian, ID (US)

(21) Appl. No.: 18/908,821

(22) Filed: Oct. 8, 2024

Related U.S. Application Data
(60) Provisional application No. 63/597,807, filed on Nov. 10, 2023.

(51) Int. Cl. G11C 11/54; G11C 11/56

(52) U.S. Cl. CPC G11C 11/54; G11C 11/5628; G11C 11/5642

(57) ABSTRACT

System-in-package (SiP) having functional high bandwidth memory (HBM) devices, and associated systems and methods are disclosed herein. In some embodiments, the functional HBM devices can include a controller die, one or more volatile memory dies, a flash memory die, and an HBM bus communicably coupled to each of the controller, volatile memory, and flash memory dies. The flash memory die can include one or more word lines that each have multiple programmable memory cells, as well as multiple bit lines. Each of the bit lines is coupled to a corresponding programmable memory cell from each of the one or more word lines. During operation, the controller die is configured to control the volatile memory dies and the flash memory die, through a shared bus therebetween, to implement one or more neural network computing operations within the functional HBM device.

### CROSS-REFERENCE TO RELATED APPLICATION(S)

The present application claims priority to U.S. Provisional Patent Application No. 63/597,807, filed Nov. 10, 2023, the disclosure of which is incorporated herein by reference in its entirety.

### TECHNICAL FIELD

The present technology is generally related to vertically stacked semiconductor devices and more specifically to stacked volatile and functional dies for semiconductor packages for neural network processing.

### BACKGROUND

Microelectronic devices, such as memory devices, microprocessors, and other electronics, typically include one or more semiconductor dies mounted to a substrate and encased in a protective covering. The semiconductor dies include functional features, such as memory cells, processor circuits, imager devices, interconnecting circuitry, etc. To meet continual demands on decreasing size, wafers, individual semiconductor dies, and/or active components are typically manufactured in bulk, singulated, and then stacked on a support substrate (e.g., a printed circuit board (PCB) or other suitable substrates). The stacked dies can then be coupled to the support substrate (sometimes also referred to as a package substrate) through bond wires in shingle-stacked dies (e.g., dies stacked with an offset for each die) and/or through substrate vias (TSVs) between the dies and the support substrate.

### BRIEF DESCRIPTION OF THE DRAWINGS

FIG. 1 is a schematic diagram illustrating an environment that incorporates a high-bandwidth memory architecture.

FIG. 2 is a schematic diagram illustrating an environment that incorporates a neural network computing device in a high-bandwidth memory architecture in accordance with some embodiments of the present technology.

FIG. 3 is a partially schematic cross-sectional diagram of a system-in-package, with a functional high-bandwidth-memory device, configured in accordance with some embodiments of the present technology.

FIG. 4 is a partially schematic exploded view of a functional high-bandwidth memory device configured in accordance with some embodiments of the present technology.

FIG. 5A is a schematic top plan view of components of a functional high-bandwidth memory device configured in accordance with some embodiments of the present technology.

FIG. 5B is a schematic routing diagram for signals through the functional high-bandwidth memory device in accordance with some embodiments of the present technology.

FIG. 6 is a schematic illustration of a neural network computing operation in accordance with some embodiments of the present technology.

FIG. 7 is a partially schematic circuit diagram of a flash memory cell configured in accordance with some embodiments of the present technology.

FIG. 8 is a partially schematic circuit diagram of cells on a flash memory device configured in accordance with some embodiments of the present technology.

FIG. 9 is a flow diagram of a process for implementing a neural network computing operation within a functional high-bandwidth memory device in accordance with some embodiments of the present technology.

FIG. 10 is a flow diagram of a process for programming a flash memory device for a neural network computing operation in accordance with some embodiments of the present technology.

FIG. 11 is a partially schematic circuit diagram of cells on a flash memory device configured in accordance with further embodiments of the present technology.

FIG. 12 is a partially schematic exploded view of a functional high-bandwidth memory device configured in accordance with further embodiments of the present technology.

The drawings have not necessarily been drawn to scale. Further, it will be understood that several of the drawings have been drawn schematically and/or partially schematically. Similarly, some components and/or operations can be separated into different blocks or combined into a single block for the purpose of discussing some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

High data reliability, high speed of memory access, lower power consumption, and reduced chip size are features that are demanded from semiconductor memory. In recent years, three-dimensional (3D) memory devices have been introduced. Some 3D memory devices are formed by stacking memory dies vertically, and interconnecting the dies using through-silicon (or through-substrate) vias (TSVs). Benefits of the 3D memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 3D memory devices contribute to higher memory access speed, lower power consumption, and chip size reduction. Example 3D memory devices include Hybrid Memory Cube (HMC) and High-Bandwidth Memory (HBM). For example, HBM is a type of memory that includes a vertical stack of dynamic random-access memory (DRAM) dies and an interface die (which, e.g., provides the interface between the DRAM dies of the HBM device and a host device).

In a system-in-package (SiP) configuration, HBM devices may be integrated with a host device (e.g., a graphics processing unit (GPU) and/or computer processing unit (CPU)) using a base substrate (e.g., a silicon interposer, a substrate of organic material, a substrate of inorganic material and/or any other suitable material that provides interconnection between GPU/CPU and the HBM device and/or provides mechanical support for the components of a SiP device), through which the HBM devices and host communicate. Because traffic between the HBM devices and host device resides within the SiP (e.g., using signals routed through the silicon interposer), a higher bandwidth may be achieved between the HBM devices and host device than in conventional systems. In other words, the TSVs interconnecting DRAM dies within an HBM device, and the silicon interposer integrating HBM devices and a host device, enable the routing of a greater number of signals (e.g., wider data buses) than is typically found between packaged memory devices and a host device (e.g., through a printed circuit board (PCB)). The high-bandwidth interface within a SiP enables large amounts of data to move quickly between the host device (e.g., GPU/CPU) and HBM devices during operation. For example, the high-bandwidth channels can be on the order of 1000 gigabytes per second (GB/s, sometimes also referred to as gigabits (Gb)). It will be appreciated that such high-bandwidth data transfer between a GPU/CPU and the memory of HBM devices can be advantageous in various high-performance computing applications, such as video rendering, high-resolution graphics applications, artificial intelligence and/or machine learning (AI/ML) computing systems and other complex computational systems, and/or various other computing applications.

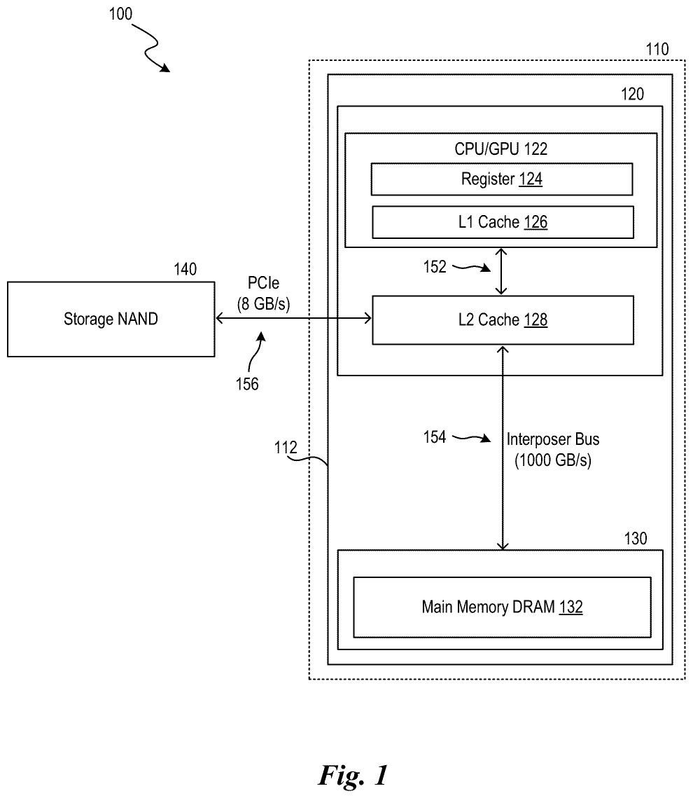

FIG. 1 is a schematic diagram illustrating an environment 100 that incorporates a high-bandwidth memory architecture. As illustrated in FIG. 1, the environment 100 includes a SiP device 110 having one or more processing devices 120 (one illustrated in FIG. 1, sometimes also referred to herein as one or more “hosts”), and one or more high-bandwidth memory (HBM) devices 130 (one illustrated in FIG. 1), integrated with a silicon interposer 112 (or any other suitable base substrate). The environment 100 additionally includes a storage device 140 coupled to the SiP device 110. The processing devices(s) 120 can include one or more CPUs and/or one or more GPUs, referred to as a CPU/GPU 122, each of which may include a register 124 and a first level of cache 126. The first level of cache 126 (also referred to herein as “L1 cache”) is communicatively coupled to a second level of cache 128 (also referred to herein as “L2 cache”) via a first communication path 152. In the illustrated embodiment, the L2 cache 128 is incorporated into the processing device(s) 120. However, it will be understood that the L2 cache 128 can be integrated into the SiP device 110 separate from the processing device(s) 120. Purely by way of example, the processing device(s) 120 can be carried by a base substrate (e.g., an interposer that is itself carried by a package substrate) adjacent to the L2 cache 128 and in communication with the L2 cache 128 via one or more signal lines (or other suitable signal route lines) therein. The L2 cache 128 may be shared by one or more of the processing devices 120 (and CPU/GPU 122 therein). During operation of the SiP device 110, the CPU/GPU 122 can use the register 124 and the L1 cache 126 to complete processing operations, and attempt to retrieve data from the larger L2 cache 128 whenever a cache miss occurs in the L1 cache 126. As a result, the multiple levels of cache can help accelerate the average time it takes for the processing device(s) 120 to access data, thereby accelerating the overall processing rates.

As further illustrated in FIG. 1, the L2 cache 128 is communicatively coupled to the HBM device(s) 130 through a second communication channel 154. As illustrated, the processing device(s) 120 (and L2 cache 128 therein) and HBM device(s) 130 are carried by and electrically coupled (e.g., integrated by) the silicon interposer 112. The second communication channel 154 is provided by the silicon interposer 112 (e.g., the silicon interposer includes and routes the interface signals forming the second communication channel, such as through one or more redistribution layers (RDLs)). As additionally illustrated in FIG. 1, the L2 cache 128 is also communicatively coupled to a storage device 140 through a third communication channel 156. As illustrated, the storage device 140 is outside of the SiP device 110, and utilizes signal routing components that are not contained within the silicon interposer 112 (e.g., between a packaged SiP device 110 and packaged storage device 140). For example, the third communication channel 156 may be a peripheral bus used to connect components on a motherboard or PCB, such as a Peripheral Component Interconnect Express (PCIe) bus. As a result, during operation of the SiP device 110, the processing device(s) 120 can read data from and/or write data to the HBM device(s) 130 and/or the storage device 140, through the L2 cache 128.

In the illustrated environment 100, the HBM devices 130 include one or more stacked volatile memory dies 132 (e.g., DRAM dies, one illustrated schematically in FIG. 1) coupled to the second communication channel 154. As explained above, the HBM device(s) 130 can be located on the silicon interposer 112, on which the processing device(s) 120 are also located. As a result, the second communication channel 154 can provide a high bandwidth (e.g., on the order of 1000 GB/s) channel through the silicon interposer 112. Further, as explained above, each HBM device(s) 130 can provide a high bandwidth channel (not shown) between the volatile memory dies 132 therein. As a result, data can be communicated between the processing device(s) 120 and the HBM device(s) 130 (and the volatile memory dies 132 therein) at high speeds, which can be advantageous for data-intensive processing operations.

Although the HBM device(s) 130 of the SiP device 110 provide relatively high bandwidth communication, their integration on the silicon interposer 112 suffers from certain shortcomings. For example, communicating data via the second communication channel 154 can require relatively large amounts of power. During a machine learning computation, such as applying a trained neural network to a dataset, the computation can require several rounds of back-and-forth communication (e.g., loading each set of inputs to the processing device(s) 120 from the HBM device(s) 130). As a result, the computations can consume large amounts of power and/or generate large amounts of heat.

HBM devices, and associated systems and methods, that address the shortcomings discussed above are disclosed herein. For example, the HBM device can include an interface die, one or more volatile memory dies (e.g., DRAM dies), and one or more computational dies (e.g., a programable NOR flash die, a programmable NAND die, and/or the like). The HBM device can also include one or more TSVs that electrically couple the interface die, the one or more volatile memory dies, and the one or more computational dies to establish communication paths therebetween. As described herein, the TSVs can provide a wide communication path (e.g., on the order of 1024 I/Os) between the interface die, the volatile memory dies, and the computational dies of the HBM device, enabling high bandwidth therebetween. In other words, the disclosed HBM device combines both volatile memory and computation dies (referred to herein as a “functional HBM device”), with high-bandwidth communication between the dies of the functional HBM device. Because the communication channel between dies is significantly shorter, however, communicating data within the functional HBM device can require significantly less power than communicating the data to a separate processing device. Further, as explained herein, the computational dies can be programmed to execute neural network computations, allowing the functional HBM device to implement a neural network computational operation fully within the functional HBM device. As a result, the functional HBM device can significantly reduce the power required to implement the neural network computational operation (and the heat generated thereby).

Additional details on the functional HBM devices, and associated systems and methods, are set out below. For ease of reference, semiconductor packages (and their components) are sometimes described herein with reference to front and back, top and bottom, upper and lower, upwards and downwards, and/or horizontal plane, x-y plane, vertical, or z-direction relative to the spatial orientation of the embodiments shown in the figures. It is to be understood, however, that the semiconductor assemblies (and their components) can be moved to, and used in, different spatial orientations without changing the structure and/or function of the disclosed embodiments of the present technology. Additionally, signals within the semiconductor packages (and their components) are sometimes described herein with reference to downstream and upstream, forward and backward, and/or read and write relative to the embodiments shown in the figures. It is to be understood, however, that the flow of signals can be described in various other terminology without changing the structure and/or function of the disclosed embodiments of the present technology.

Further, although the memory device architectures disclosed herein are primarily discussed in the context of implementing neural network computational operations fully within an HBM device, one of skill in the art will understand that the scope of the technology is not so limited. For example, the systems and methods disclosed herein can also be deployed to implement various other computational operations fully within an HBM device (e.g., for various other machine learning applications).

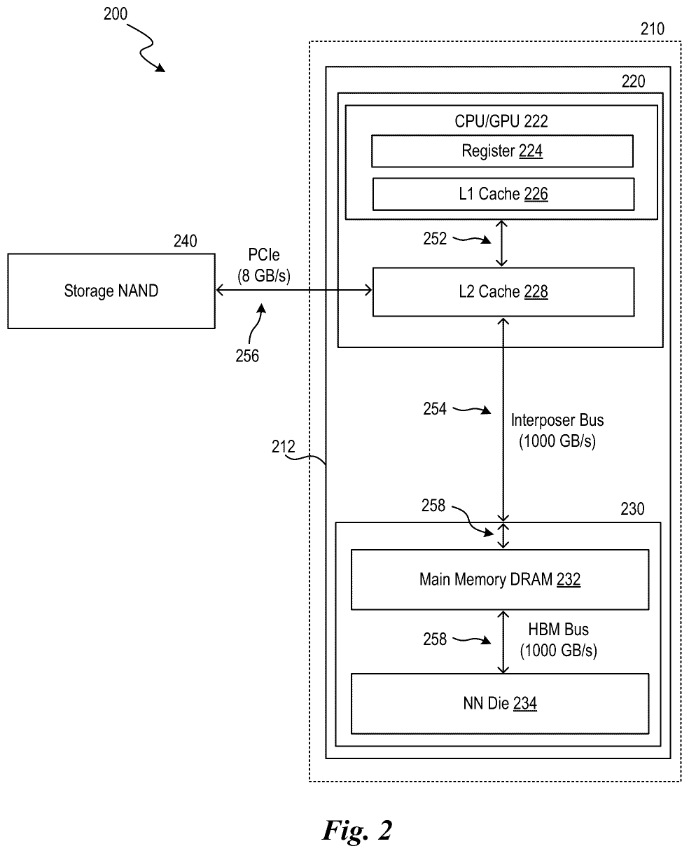

FIG. 2 is a schematic diagram illustrating an environment 200 that incorporates an HBM architecture in accordance with some embodiments of the present technology. Similar to the environment 100 discussed above, the environment 200 includes a SiP device 210 having one or more processing devices 220 (one illustrated in FIG. 2) and one or more storage devices 240 (one illustrated in FIG. 2). However, in contrast to the SiP device 110 described in FIG. 1, embodiments of the SiP device 210 illustrated in FIG. 2 includes one or more functional HBM devices 230 (one illustrated in FIG. 2), described further below. The processing device(s) 220 and the functional HBM device(s) 230 are each integrated on an interposer 212 (e.g., a silicon interposer, another organic interposer, an inorganic interposer, and/or any other suitable base substrate) that can include one or more signal routing lines. The processing device(s) 220 is driven by a CPU/GPU 222 that includes a register 224 and an L1 cache 226. The L1 cache 226 is communicatively coupled to an L2 cache 228 via a first communication channel 252. Further, the L2 cache 228 is communicatively coupled to the functional HBM devices 230 through a second communication channel 254 and to the storage device 240 through a third communication channel 256. Still further, the second communication channel 254 can have a relatively high bandwidth (e.g., on the order of 1000 GB/s) while the third communication channel 256 can have a relatively low bandwidth (e.g., on the order of 8 GB/s).

In the embodiment illustrated in FIG. 2, the functional HBM device(s) 230 each include a stack of one or more volatile memory dies 232 (e.g., DRAM dies) as well as one or more functional dies 234 (e.g., programmable NOR flash dies for neural networking computations, programmable NAND dies, or other suitable functional dies). That is, the one or more volatile memory dies 232 and the one or more functional dies 234 can be vertically stacked in the functional HBM device 230. Within the stack, the memory dies 232 and the functional dies 234 can be communicably coupled by a fourth communication channel 258 (e.g., an HBM bus) that can have a relatively high bandwidth (e.g., on the order of 1000 GB/s). As a result, data can be communicated quickly and efficiently within the functional HBM device(s) 230. As discussed in more detail below, the functional dies 234 can be used to complete one or more complex computations within the functional HBM device(s) 230, such as various neural networking computations, machine learning computations, and/or other suitable computations. As also discussed in more detail below, each of the volatile memory and functional dies 232, 234 can be coupled to a high bandwidth bus in the functional HBM device(s) 230. For example, each of the functional HBM devices 230 can include multiple TSVs that interconnect the volatile memory dies 232 and the functional dies 234 within the functional HBM device 230, thereby providing a high bandwidth bus.

The combination of volatile memory and functional dies within each functional HBM device 230 can provide certain advantages. For example, the one or more volatile memory dies 232 can store the weights associated with a trained neural network and/or values associated with inputs into the neural network. In this example, as discussed in more detail below, the functional HBM device 230 can program the weights into the one or more functional dies 234 via the TSVs, then write the inputs into the one or more functional dies 234 and read a result to complete one or more neural network computing operations. That is, the functional HBM device 230 can complete any number of neural network computing operations without communicating data to the processing device(s) 220 via the second communication channel 254. Communicating data via the TSVs can be faster than communicating data via the second communication channel 254 and/or can require less energy than communicating data via the second communication channel 254. Thus, by completing the neural network computing operations internally, the functional HBM device can expedite the neural network computing operations and/or reduce the power requirements to operate the environment 200. Further, the reduced power consumption can reduce the heat generated by the environment 200 that can have deleterious effects (e.g., data losses).

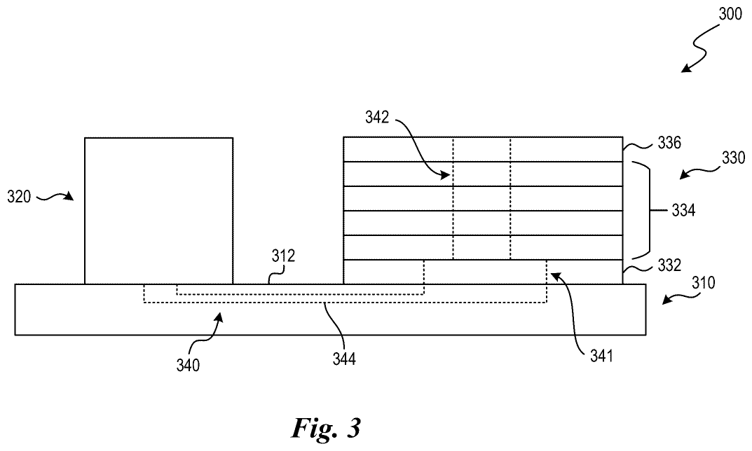

The environment 200 can be configured to perform any of a wide variety of suitable computing, processing, storage, sensing, imaging, and/or other functions for a variety of electronic devices. For example, representative examples of systems that include the environment 200 (and/or components thereof, such as the SiP device 210) include, without limitation, computers and/or other data processors, such as desktop computers, laptop computers, Internet appliances, hand-held devices (e.g., palm-top computers, wearable computers, cellular or mobile phones, automotive electronics, personal digital assistants, music players, etc.), tablets, multi-processor systems, processor-based or programmable consumer electronics, network computers, and minicomputers. Additional representative examples of systems that include the environment 200 (and/or components thereof) include lights, cameras, vehicles, etc. With regard to these and other examples, the environment 200 can be housed in a single unit or distributed over multiple interconnected units, e.g., through a communication network, in various locations on a motherboard, and the like. Further, the components of the environment 200 (and/or any components thereof) can be coupled to various other local and/or remote memory storage devices, processing devices, computer-readable storage media, and the like. Additional details on the architecture of the environment 200, the SiP device 210, the functional HBM device(s) 230, and processes for operation thereof, are set out below with reference to FIGS. 3 through 12.

FIG. 3 is a partially schematic cross-sectional diagram of a SiP device 300, with a functional HBM device 330, configured in accordance with some embodiments of the present technology. As illustrated in FIG. 3, the SiP device 300 includes a base substrate 310 (e.g., a silicon interposer, another suitable organic substrate, an inorganic substrate, and/or any other suitable material), as well as a CPU/GPU 320 and the functional HBM device 330 each integrated with an upper surface 312 of the base substrate 310. In the illustrated embodiments, the CPU/GPU 320, and associated components (e.g., the register, L1 cache, and the like) is illustrated as a single package, and the functional HBM device 330 includes a stack of semiconductor dies. The stack of semiconductor dies in the functional HBM device 330 includes an interface die 332, one or more volatile memory dies 334 (four illustrated in FIG. 3), and one or more functional dies 336 (one illustrated in FIG. 3). The CPU/GPU 320 is coupled to the functional HBM device 330 through a high bandwidth bus 340 that includes one or more route lines 344 (two illustrated schematically in FIG. 3) formed into (or on) the base substrate 310. In various embodiments, the route lines 344 can include one or more metallization layers formed in one or more RDL layers of the base substrate 310 and/or one or more vias interconnecting the metallization layers and/or traces. Further, although not illustrated in FIG. 3, it will be understood that the CPU/GPU 320 and the functional HBM device 330 can each be coupled to the route lines 344 via solder structures (e.g., solder balls), metal-metal bonds, and/or any other suitable conductive bonds.

As discussed in more detail below, the high bandwidth bus 340 can also include a plurality of through substrate vias (TSVs) 342 extending from the interface die 332, through the volatile memory dies 334, to the functional die 336. The TSVs 342 allow each of the dies to communicate data within the functional HBM device 330 (e.g., between the volatile memory dies 334 (e.g., DRAM dies) and the functional die 336 (e.g., a programable NOR die)) at a relatively high rate (e.g., on the order of 1000 GB/s or greater). Additionally, the functional HBM device 330 can include one or more signal route lines 341 (e.g., additional TSVs extending through the interface die 332) that couple the interface die 332 and/or the TSVs 342 to the route lines 344. In turn, the signal route lines 341, TSVs 342, and route lines 344 allow the dies in the functional HBM device 330 and the CPU/GPU 320 to communicate data at the high bandwidth.

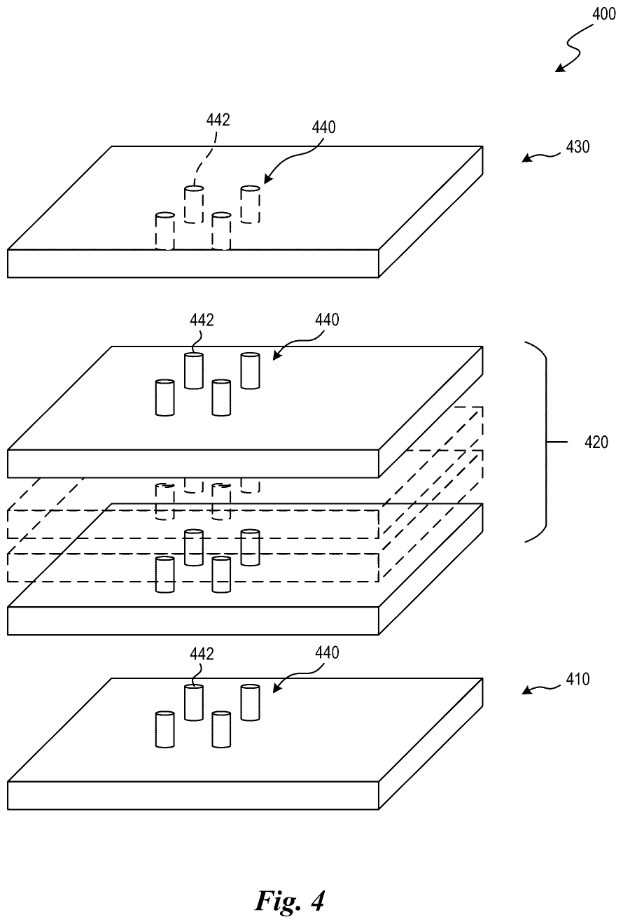

FIG. 4 is a partially schematic exploded view of a functional HBM device 400 configured in accordance with some embodiments of the present technology. For example, the functional HBM device 400 can be used as the functional HBM device 330 discussed above with reference to FIG. 3. In the illustrated embodiment, the functional HBM device 400 is a stack of dies that includes an interface die 410, one or more volatile memory dies 420 (four illustrated in FIG. 4), and one or more functional dies 430 (one illustrated in FIG. 4). Further, the functional HBM device 400 includes a shared HBM bus 440 communicatively coupling the interface die 410, the volatile memory dies 420, and the functional die 430.

The interface die 410 can be a physical layer (“PHY”) that establishes electrical connections between the shared HBM bus 440 and external components of the shared HBM bus 440 (e.g., the route lines 344 of FIG. 3). Additionally, or alternatively, the interface die 410 can include one or more active components, such as a static random access memory (SRAM) cache, a memory controller, and/or any other suitable components. The volatile memory dies 420 (sometimes also referred to collectively herein as a “main memory”) can be DRAM memory dies that provide low latency memory access to the functional HBM device 400. The functional die 430 (sometimes referred to herein as a “programmable memory die,” a “flash memory die,” a “computing die,” and the like) can provide programmable computational functionality for the functional HBM device 400. In a specific, non-limiting example, the functional die can be a NOR flash die that includes one or more word lines that each couple to one or more memory cells with programable threshold voltages. Each of the memory cells is coupled to a corresponding bit line and a common source line (sometimes also referred to herein as “shared source line”). In some embodiments, at least some (up to all) of the memory cells that are coupled to the same word line are also coupled to the same shared source line. In this example, a constant voltage can be applied to the word line (e.g., several volts, tens of volts, and/or the like), while input voltages are applied to each of the bit lines (e.g., a negative voltage with an absolute value of several volts, tens of volts, and/or the like) coupled to the individual memory cells that share the word line. As a result, each of the individual memory cells drive a current to the common source line, such that the current on the common source line reflects the sum of the currents that are output by each of the individual memory cells (i.e., the common source line sums or accumulates the currents from the memory cells coupled to it). As discussed in more detail below, this summing function (and/or an activation function applied to the summed currents) can be utilized to implement a neural network computing operation. For example, the programable threshold voltage at each of the memory cells coupled to the word line can correspond to an individual weight from a trained neural network, while the voltage applied to each bit line corresponds to an individual input value. In this example, the operations above multiply a weight vector with an input vector and provide the result as an output current on the source line, thereby implementing a neural network computing operation.

In the illustrated embodiment, the shared HBM bus 440 includes a plurality of TSVs 442 (four illustrated in FIG. 4, but any suitable number of TSVs is possible) extending from the interface die 410, through the volatile memory dies 420, to the functional die 430. Each of the TSVs 442 can support an independent, bidirectional read/write operation to communicate data between the dies in the functional HBM device 400 (e.g., between the interface die 410 and the volatile memory dies 420, between the functional die 430 and the volatile memory dies 420, and the like). Because the TSVs 442 establish the shared HBM bus 440 between each of the dies in the functional HBM device 400, the shared HBM bus 440 can reduce (or minimize) the footprint needed to establish high bandwidth communication routes through the functional HBM device 400. As a result, the shared HBM bus 440 can reduce (or minimize) the overall footprint of the functional HBM device 400.

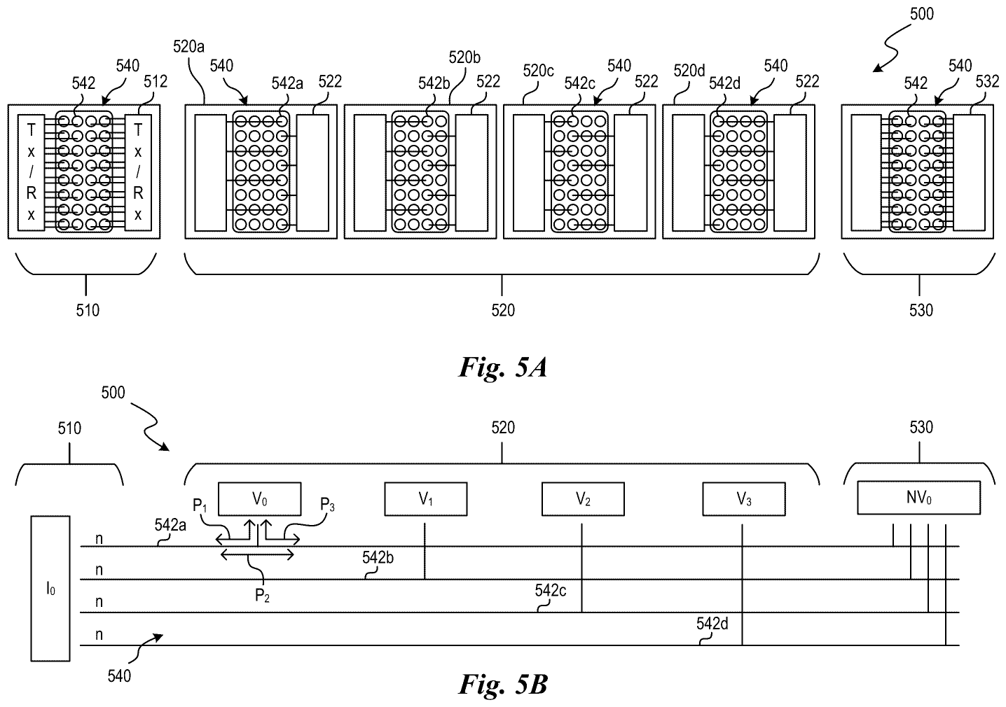

FIG. 5A is a schematic top plan view of components of a functional HBM device 500 configured in accordance with some embodiments of the present technology. As illustrated in FIG. 5A, the functional HBM device 500 is generally similar to the functional HBM device 400 described above with reference to FIG. 4. For example, the functional HBM device 500 includes an interface die 510, one or more volatile memory dies 520 (four illustrated in FIG. 5A), and one or more functional dies 530 (one illustrated in FIG. 5A), as well as a shared HBM bus 540 communicatively coupling the interface die 510, the volatile memory dies 520, and the functional die 530.

The interface die 510 includes one or more read/write components 512 (two illustrated in FIG. 5A). In various embodiments, the read/write components 512 can couple the interface die 510 to an external component (e.g., to the base substrate 310 of FIG. 3), present information on the functional HBM device 500 and/or dies of the functional HBM device 500 to an external component (e.g., the CPU/GPU 320 of FIG. 3), and/or include memory controlling functionality to control movement of data between the volatile memory dies 520 and/or the functional die 530. In some embodiments, the interface die 510 includes one or more controller components that are coupled to the volatile memory dies 520 and the functional die 530 to implement various computational operations within the functional HBM device 500 (e.g., to read weights for a neural network processing operation from the volatile memory dies 520, program the functional die 530 with the weights, write one or more inputs to the functional die 530 from the volatile memory dies 520, and read a result from the functional die 530). The volatile memory dies 520 each include memory circuits 522 (e.g., lines of capacitors and/or transistors) that can store data in volatile arrays. The functional die 530 includes memory circuits 532 (e.g., NOR flash memory circuits) that include a plurality of programmable memory cells. As described herein, the programmable memory cells may be programmed (e.g., by a write operation) with programmable threshold voltages.

As further illustrated in FIG. 5A, the shared HBM bus 540 can include a plurality of TSVs 542 (thirty-two illustrated in FIG. 5A) that extend between each of the interface die 510, the volatile memory dies 520, and the functional die 530. The TSVs 542 can be organized into subgroups (e.g., rows, columns, and/or any other suitable subgrouping) that are selectively coupled to the dies in the functional HBM device 500 to simplify signal routing. For example, in the embodiment illustrated in FIG. 5A, a first volatile memory die 520a can be selectively coupled to a first subgrouping 542a of the TSVs 542 (e.g., the right-most column of the TSVs 542). Accordingly, read/write operations on the first volatile memory die 520a must be performed through the first subgrouping 542a of the TSVs 542. Similarly, as further illustrated in FIG. 5A, a second volatile memory die 520b can be selectively coupled to a second subgrouping 542b of the TSVs 542, a third volatile memory die 520c can be selectively coupled to a third subgrouping 542c of the TSVs 542, and a fourth volatile memory die 520d can be selectively coupled to a fourth subgrouping 542d of the TSVs 542. In the illustrated embodiment, each of the first-fourth subgroupings 542a-542d is completely separate from the other subgroupings. As a result, each of the volatile memory dies 520 is fully separately addressed, despite being coupled to the shared HBM bus 540. However, it will be understood that, in some embodiments, the first-fourth subgroupings 542a-542d can share one or more of the TSVs 542, that each of the first-fourth volatile memory dies 520a-520d can be coupled to a shared subgrouping of the TSVs 542, and/or the TSVs 542 can include a fifth subgrouping coupled to each of the first-fourth volatile memory dies 520a-520d to allow one or more read/write operations to send data to multiple of the first-fourth volatile memory dies 520a-520d at once (e.g., allowing the second volatile memory die 520b to store a copy of the data for the first volatile memory die 520a).

In the embodiment illustrated in FIG. 5A, the interface die 510 is coupled to each of the TSVs 542. As a result, the interface die 510 can clock and help route read/write signals to any suitable destination. Similarly, the functional die 530 is coupled to each of the TSVs 542. As a result, the functional die 530 can use any available subgrouping of the TSVs 542 (and/or all of the TSVs 542) to send and/or receive read/write signals.

FIG. 5B is a schematic routing diagram for signals through the functional HBM device 500 of FIG. 5A in accordance with some embodiments of the present technology. In FIG. 5B, the TSVs 542 are represented schematically by horizontal lines while the connections to the TSVs 542 (e.g., by the volatile memory dies 520 and the functional die 530) are illustrated by vertical lines that intersect with the horizontal lines. It will be understood that each intersection can represent a connection to one or more of the TSVs 542 (e.g., eight of the TSVs 542 illustrated in each of the first-fourth subgroupings 542a 542d of FIG. 5A, a single TSV, two TSVs, and/or any other suitable number of connections).

In the embodiment illustrated in FIG. 5B, the volatile memory dies 520 are selectively coupled to the first-fourth subgroupings 542a-542d of the TSVs 542 while interface die 510. For example, a first volatile link V0 (corresponding to the first volatile memory die 520a of FIG. 5A) is coupled to the first subgrouping 542a, a second volatile link V1 (corresponding to the second volatile memory die 520b) is coupled to the second subgrouping 542b, a third volatile link V2 (corresponding to the third volatile memory die 520c of FIG. 5A) is coupled to the third subgrouping 542c, and a fourth volatile link V3 (corresponding to the fourth volatile memory die 520d of FIG. 5A) is coupled to the fourth subgrouping 542d. Further, the functional die 530 is coupled to each of the first-fourth subgroupings 542a 542d of the TSVs 542 (e.g., at a non-volatile link NVO). As a result, for example, a signal from the interface die 510 (e.g., a read request) can be written (via an interface link I0) onto the second subgrouping 542b. Consequently, the signal can only be received by the second volatile link V1 (e.g., the second volatile memory die 520b of FIG. 5A) and/or the functional die 530. The second volatile memory die 520b can then write the requested data onto the second subgrouping 542b, which can then only be received by the interface die 510 and the functional die 530.

As further illustrated in FIG. 5B, signals in the functional HBM device 500 can move along any of three bidirectional paths between any two of the interface die 510, one of the volatile memory dies 520, and the functional die 530. For example, a first signal path P1 extends between the interface die 510 and the volatile memory dies 520. The first signal path P1 can be used during normal operation of the functional HBM device 500 to perform any number of read/write operations between the interface die 510 (and any suitable component beyond, such as the CPU/GPU 320 of FIG. 3 and/or the storage device 240 of FIG. 2) and the volatile memory dies 520. For example, the first signal path P1 can be used to load weights for a trained neural network and/or inputs for various neural network computations onto the volatile memory dies 520. A second signal path P2 extends between the volatile memory dies 520 and the functional die 530. The second signal path P2 can be used to write a subset of the data in the volatile memory dies 520 (e.g., weights and/or input values for a neural network processing operation) from the volatile memory dies 520 to the functional die 530, write results of some computer processing at the functional die 530 to the volatile memory dies 520 and, and/or perform any other suitable operation. A third signal path P3 extends between the interface die 510 and the functional die 530. The third signal path P3 can be used to write a result of one or more neural network processing operations to the interface die 510 (e.g., to be communicated external to the functional HBM device 500) and/or perform any other suitable operation. Because the operations described above with reference to the first-third signal travel paths P1-P3 use the high bandwidth channels (i.e., the TSVs 542 in the shared HBM bus 540), the operations can be completed at a relatively fast rate, with relatively low power requirements, and/or while generating relatively low amounts of heat (e.g., compared to performing the same read/write operations external to the functional HBM device 500).

The bidirectional restriction of each of the TSVs 542 in the illustrated embodiment prevents any subset of the TSVs 542 from being used for multiple operations at the same time (e.g., along the first and third travel paths P1, P3 at the same time). However, it will be understood that, in some embodiments, one or more of the signal travel paths can have multiple destinations. For example, a write operation to one of the volatile memory dies 520 along the first signal travel path P1 can write data to the functional die 530 along the third signal travel path P-3 at the same time. Further, the first subgrouping 542a can be used for a first operation (e.g., writing data to the functional die 530 from one of the volatile memory dies 520 along the third signal travel path P3) at the same time the second subgrouping 542b is used for a second operation (e.g., writing data from the interface die 510 to one of the volatile memory dies 520 along the first signal travel path P1). Still further, as discussed in more detail below, the shared HBM bus 540 can include additional TSVs and/or additional subgroupings of the TSVs to allow subgroupings to be dedicated to various signal travel paths at the cost of the shared HBM bus 540 having a larger footprint.

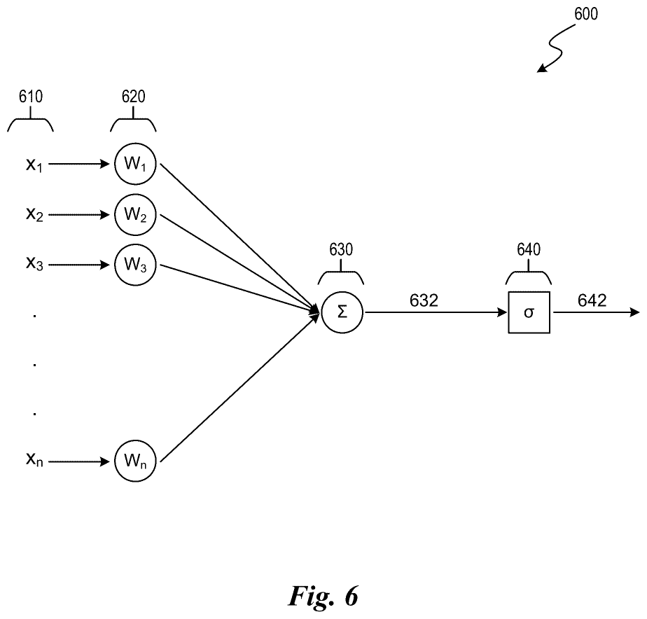

FIG. 6 is a schematic illustration of a neural network computing operation 600 in accordance with some embodiments of the present technology. The neural network computing operation 600, sometimes also referred to as an “artificial neuron,” receives one or more inputs in an input vector 610, multiplies each of the inputs with a corresponding weight via a weight vector 620, then applies a sum function 630 (sometimes also referred to as a transfer function) to sum each of the weighted inputs in an initial output 632. The result can then be passed through an activation function 640 to produce a final output 642 (sometimes also referred to as an “activation”). In some embodiments, the activation function 640 generates a binary output based on the sum of the weighted inputs in the initial output 632 (e.g., 0 if the sum is below a predetermined threshold and 1 if the sum is at or above the predetermined threshold). In some embodiments, the activation function 640 passes the value of the weighted sum in the initial output 632 onward if the weighted sum is at or above a predetermined threshold, else outputs a predetermined value (e.g., 0). In some embodiments, the activation function 640 filters the weighted sum in the initial output 632 to a value in a predetermined range (e.g., generates a number between 0 and 1).

In a specific, non-limiting example, the inputs can be image values for pixels in an image and the weights can be based on an importance of the values in detecting an individual's face in the image. In various embodiments, the weights can be based on a learned importance for the values (e.g., learned during a training process for the neural network computing operation 600) and/or loaded from a database (e.g., based on a prior training model). When the weighted sum is above a predetermined threshold, the activation function 640 can set the final output 642 to 1 (corresponding to a detection of the individual's face). Otherwise, the activation function 640 can set the final output 642 to 0 (corresponding to a non-detection of the individual's face). In some related examples, the weights correspond to the importance of the values in detecting an individual's face from a first angle. In such examples, the process can be repeated with a second weight vector corresponding to the importance of the values in detecting an individual's face from a second angle. In some related examples, the weights correspond to an importance in calculating one or more features of the individual's face. In such examples, the process can be repeated for a plurality of features to generate a plurality of the final outputs 642. The final outputs 642 can then be input into another neural network computing operation that generates a final output corresponding to a detection or non-detection of the individual's face.

Because the neural network computing operation 600 is based on logical operations applied to the input vector 610 and weight vector 620 (e.g., generating a sum of weighted inputs), the neural network computing operation 600 can be implemented via a plurality of flash memory cells coupled to a shared source line, where each flash memory cell generates a current corresponding to a weighted input, and the shared source line captures a total current corresponding to the sum of weighted inputs. The operation of an individual flash memory cell, and array of flash memory cells, that provide a neural network computing operation is described further below.

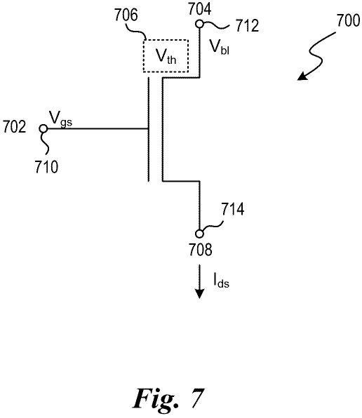

FIG. 7 is a partially schematic circuit diagram of an individual flash memory cell 700 configured in accordance with some embodiments of the present technology. The flash memory cell 700 may be part of a functional die (e.g., programmable NOR flash die for neural networking computations) of a functional HBM device. In the illustrated embodiment, the flash memory cell 700 is implemented with an NMOS transistor (e.g., as a single NOR flash cell). However, it will be appreciated that in embodiments the flash memory cell 700 can be implemented differently (e.g., with a PMOS transistor as a NAND flash cell). The flash memory cell 700 includes a gate terminal 710, a drain terminal 712, and a source terminal 714. The gate terminal 710 may be coupled to a word line 702, the drain terminal 712 may be coupled to a bit line 704, and the source terminal 714 may be coupled to a source line 708. As described herein, the word line 702 and/or source line 708 may be shared by other flash memory cells 700 in a row (or column and/or other suitable line (linear or non-linear)), and/or the bit line 704 may be shared by other flash memory cells 700 in a column (or row and/or other suitable line (linear or non-linear)). The flash memory cell 700 may also be associated with a threshold 706. As described herein, the threshold 706 may be programmed differently for individual flash memory cells 700.

During operation, when a bit line voltage V_{bl}, applied to the bit line 704, is much less than the difference between a word line voltage V_{gs} applied to the word line 702 and the threshold 706 (i.e., a threshold voltage Vₜₕ), the flash memory cell 700 generates an output current (I_{ds}), supplied to the source line 708, given by:

$${I}_{ds} = k ( {V}_{gs} - {V}_{th} ) * {V}_{bl} \qquad ( 1 )$$

where k is a process-related constant. As discussed in more detail below, the threshold voltage Vₜₕ can be programmed into the flash memory cell 700.

To complete one or more operations related to a neural networking computation, an individual weight from the weight vector 620 (FIG. 6) can be translated from the result of k*(Vgs−Vth), which can then be used to program the threshold voltage Vₜₕ of an individual flash memory cell (e.g., a flash memory cell 700). A corresponding individual input the input vector 610 (FIG. 6) can then be translated to the bit line voltage V_{bl} and applied to the flash memory cell, resulting in an output current I_{ds} that can be translated to the weighted input. The output current I_{ds} can then be driven on the shared source line that sums output currents from a plurality of similar flash memory cells, thereby mimicking the sum function 630 of FIG. 6. The process can then be repeated any number of times with different inputs on the bit line voltage V_{bl} to implement additional neural networking computations with the same weight vector.

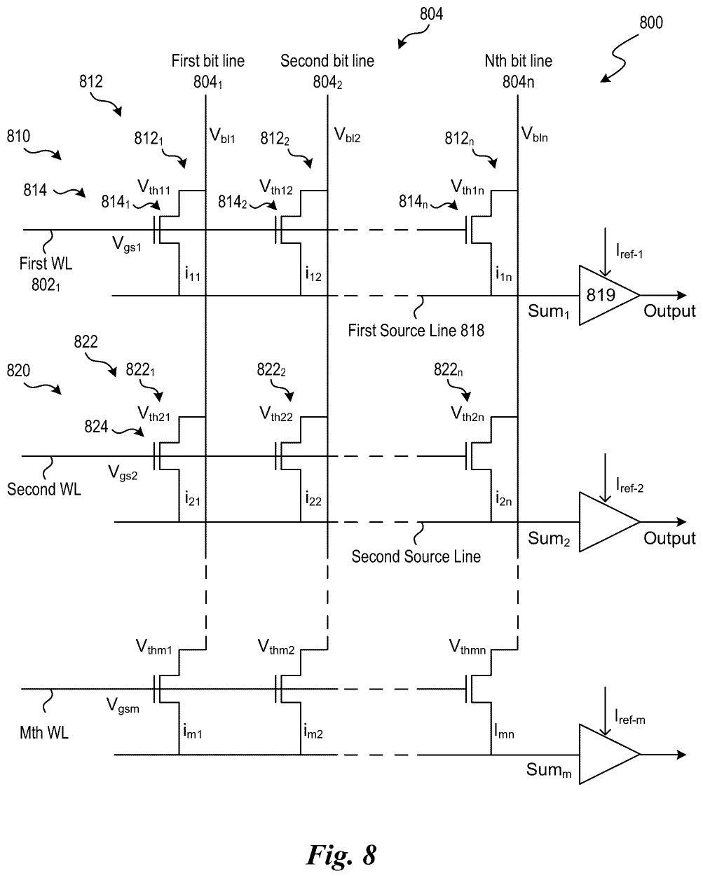

FIG. 8 is a partially schematic circuit diagram of a flash memory device 800 configured in accordance with some embodiments of the present technology. The flash memory device 800 may be part of a functional die (e.g., programmable NOR flash die for neural networking computations) of a functional HBM device. In the illustrated embodiment, the flash memory device 800 includes a first row 810 that includes a plurality of first flash memory cells 812 (n-number illustrated in FIG. 8), a second row 820 that includes a plurality of second flash memory cells 822 (n-number illustrated in FIG. 8), up to and including a Mth row. Each of the first and second flash memory cells 812, 822 is generally similar to the flash memory cell 700 discussed above with reference to FIG. 7. For example, a first-first flash memory cell 812₁ in the first row 810 includes a gate terminal coupled to a first word line 802₁, a drain terminal coupled to a first bit line 804₁, a first-first threshold voltage 814₁, and a source terminal coupled to a first source line. In the illustrated embodiment, the first word line 802₁ is shared by each of the first flash memory cells 812 (e.g., 812₁ through 812ₙ) in the first row 810 to apply the same (e.g., a constant) first word line voltage V_{gs1} to each of the first flash memory cells 812. Further, each of the first flash memory cells 812 outputs a current to the first source line 818 in an additive manner (e.g., the first source line 818 is a shared and/or common source line that sums the output currents from the first flash memory cells 812 in the first row 810). The first source line 818 then passes through a first filter circuit 819.

To mimic an artificial neuron (e.g., of the type discussed above with reference to FIG. 6), each of the first threshold voltages 814 is programmed based on a weight vector (e.g., the weight vector 620 of FIG. 6). More specifically, the first-first threshold voltage 814₁ is programmed such that a difference between a first-first threshold voltage Vₜₕ₁₁ and the first word line voltage V_{gs1} corresponds to a first weight in the weight vector for artificial neuron; a second-first threshold 8142 is programmed such that a difference between a second-first threshold voltage Vₜₕ₁₂ and the first word line voltage V_{gs1} corresponds to a second weight in the weight vector; and so on to the nth-first threshold 814ₙ. In other words, each of the first flash memory cells 812 associated with the row 810 may be programmed with individual threshold voltages corresponding to different weights in a weight vector.

Inputs from an input vector (e.g., the input vector 610 of FIG. 6) can then be translated to bit line voltages V_{bl1-n} that are loaded onto the bit lines 804 (e.g., V_{bl1} loaded onto 804₁, V_{bl2} loaded onto 804₂, and so on), resulting in a plurality of first output currents being output to the first source line 818. For example, a first-first output current in from the first-first flash memory cell 812₁ is output to the first source line 818; second-first output current 112 from a second-first flash memory cell 812₂ is output to the first source line 818; and so on to an nth-first output current in from a nth-first flash memory cell 812ₙ.

The first filter circuit 819 can then act as an activation function for the artificial neuron. For example, as discussed above, the first filter circuit 819 can set a value of a final output from the first row 810 to 0 if the sum on the first source line 818 is below a predetermined threshold, else the first filter circuit 819 can set the value of the final output to 1. In various other examples, the first filter circuit 819 can adjust the final output to a value within a range (e.g., from 0 to 1); set the value of the final output to 0 if the sum on the first source line 818 is below a predetermined threshold, and otherwise set the final output to the sum; set the value of the final output to 1 if the sum on the first source line 818 is above a predetermined threshold, and otherwise set the final output to the sum; scale the final output; and/or apply various other suitable activation function filters.

As further illustrated in FIG. 8, the second flash memory cells 822 in the second row 820 can include second threshold voltages 824 that are programmable independent from the first threshold voltages 814. Further, the bit lines 804 can be shared by corresponding first and second flash memory cells 812, 822. For example, the first bit line 804₁ is shared by the first-first flash memory cell 812₁ of the first row 810 and a first-second flash memory cell 822₁ on the second row 820; the second bit line 804₂ is shared by the second-first flash memory cell 812₂ of the first row 810 and a second-second flash memory cell 8222 on the second row 820; and so on to an nth-first flash memory cell 812, and an nth-second flash memory cell 822ₙ sharing an nth bit line 804ₙ. As a result, the first row 810 can act as a first artificial neuron, associated with a first set of weights, for a set of inputs while the second row 820 acts as a second artificial neuron, associated with a second set of weights, for the same set of inputs to execute separate neural network computing operations at the same time (or generally the same time).

In a specific, non-limiting example, the first row 810 can be programmed with weights that allow the first artificial neuron to detect an individual's face in an image at a first angle while the second row 820 can be programmed with weights that allow the second artificial neuron to detect the individual's face in the image at a second angle. In this example, input values from the image can be provided on the bit lines 804 shared by both the first and second row 810, 820, thereby allowing the flash memory device 800 to quickly execute multiple neural network computing operations to detect the individual's face in the image.

It will be understood that although the operation of the flash memory device 800 has been discussed with reference to two rows (e.g., the first row 810 and the second row 810), the flash memory device 800 can include any suitable number of rows, each of which may be programmed based on different weight vectors. For example, in various embodiments, the flash memory device 800 can include ten rows, one hundred rows, one thousand rows, ten thousand rows, and/or any other suitable number of rows. As described above, each row may include a plurality of flash memory cells coupled to a shared word line and/or shared source line associated with the row. Further, the n-number of flash memory cells in any one of the rows can be one memory cell, two memory cells, ten memory cells, one hundred memory cells, one thousand memory cells, ten thousand memory cells, and/or any other suitable number of memory cells. Still further, different rows in the flash memory device 800 can have different numbers of flash memory cells. Purely by way of example, the first row 810 can include ten thousand memory cells while the second row 820 can include one thousand memory cells. The additional memory cells in the first row 810 can allow more complex neural network computing operations. The fewer number of memory cells in the second row can simplify and/or accelerate neural network computing operations (e.g., by requiring fewer flash memory cells to be programmed). In some embodiments, only some of the flash memory cells within a row are programmed.

It will be understood that although the flash memory device 800 has been described herein as having flash memory cells arranged in horizontal rows, the technology described herein is not so limited. For example, in various embodiments, groups of memory cells can be coupled to a shared word line and/or source line in columns (e.g., with bit lines arranged in rows), coupled to a shared word line and/or source line along non-linear lines, and/or the like. Accordingly, as used herein, “row” is to be understood as referring to a group of one or more memory cells communicably coupled to a shared word line and/or shared source line, irrespective of the positional distribution of the memory cells and/or orientation of the shared word line and/or shared source line.

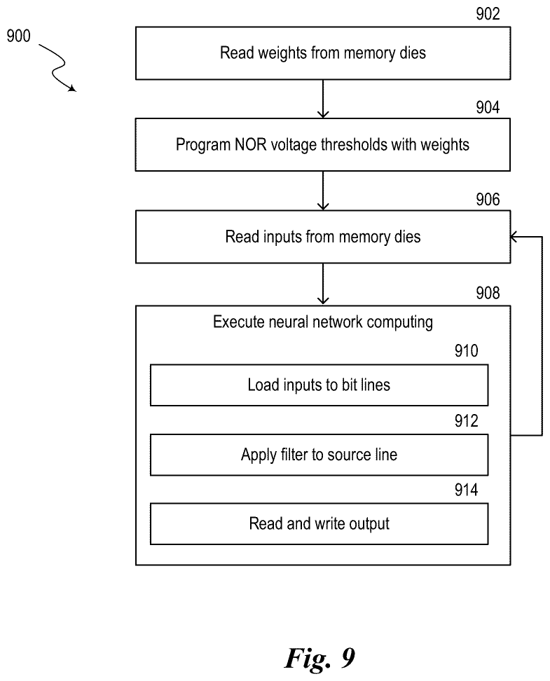

FIG. 9 is a flow diagram of a process 900 for implementing one or more neural network computing operations within a functional HBM device in accordance with some embodiments of the present technology. The process 900 can be executed, for example, by one or more controllers on an interface die (e.g., the interface die 332 of FIG. 3; the interface die 410 of FIG. 4; and/or the interface die 510 of FIG. 5A). As a result, the process 900 can be completed fully within the function HBM device to reduce the power and time needed for the process 900 and/or to reduce the heat generated by the process 900.

The process 900 begins at block 902 by reading one or more weights from memory dies in the functional HBM device. The weights can correspond to a weight vector (e.g., the weight vector 620 of FIG. 6) for one or more or more trained neural network operations. The reading at block 902 can be completed using an HBM bus, such as one or more TSVs coupled between an interface die, the memory dies, and/or one or more functional dies (e.g., the TSVs 442 of FIG. 4, the TSVs 542 of FIG. 5A, and/or the like).

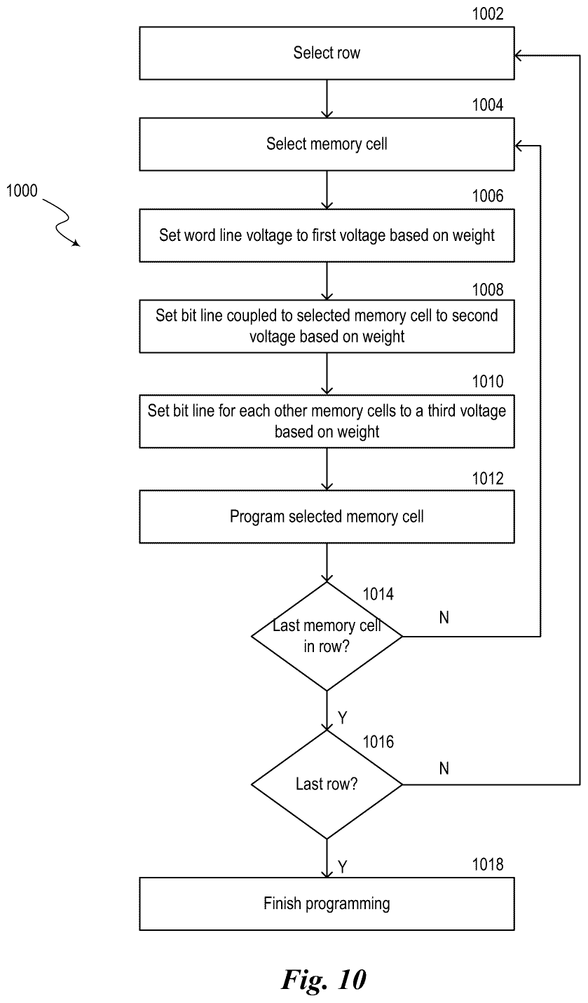

At block 904, the process 900 includes programming the weights into the functional die(s) in the functional HBM device. For example, as discussed above, the threshold voltages for NOR flash memory cells can be programmed based on the weights for a desired neural network computing operation. Additional details on an exemplary process for programming the threshold voltages are discussed below with respect to FIG. 10. In some embodiments, the process 900 can cycle through blocks 902, 904 to read and program weights for a plurality of neural network computing operations (e.g., to program multiple word lines with different weights). In some embodiments, the process 900 can program each different row in one cycle through blocks 902, 904 (e.g., by reading multiple weight vectors at block 902 and then programming the flash memory cells belonging to the rows at block 904).

At block 906, the process 900 includes reading inputs from the memory dies (e.g., one or more input vectors). The inputs can correspond to data that will be processed by the neural network computing operation(s), such as one or more images, one or more videos, one or more text files, and/or any other suitable inputs. The reading at block 902 can be completed using an HBM bus, such as one or more TSVs coupled between an interface die, the memory dies, and/or one or more functional dies.

At block 908, the process 900 includes executing the one or more neural network computing operations at the functional die. In the illustrated embodiment, executing the one or more neural network computing operations includes executing various sub-processes. Returning to the example of a NOR flash memory die for illustration, executing the neural network computing operations can include loading the inputs onto one or more bit lines in the NOR flash memory die at block 910 (e.g., loading the inputs onto the bit lines 804 of FIG. 8) while applying a constant voltage to each word line. In various examples, the constant voltage can be between about 1 volt and about 100 volts (e.g., several volts to tens of volts), between about 5 volts and about 50 volts, and/or any other suitable voltage. As a result, each flash memory cell (e.g., each first flash memory cell 812 in the first row 810 coupled to the first word line 802₁ of FIG. 8) will output a current onto a source line for the first row (e.g., the first source line 818 of FIG. 8) that corresponds to an individual operation of an input multiplied by a weight programmed into the flash memory cell (i.e., an individual operation from the vector multiplication in the neural network computing operation). The output currents from each of the flash memory cells are summed on the source line, thereby performing the summation required for the neural network computing operation. The process 900 then applies a filter to the current on the source line at block 912. For example, the filter can be the comparison of the source line current to a reference current at the first filter circuit 819 of FIG. 8. The filter mimics an activation function for the neural network computing operation to generate a final output that can be binary (emulating a firing neuron), a varying value between an upper and lower bound (e.g., between zero and one), and/or various other suitable outputs from an activation function discussed in more detail above. The process 900 then reads the output at block 914 and writes the output to a suitable destination (e.g., to the memory dies, the interface die, and/or a suitable external component (e.g., the CPU/GPU 320 of FIG. 3) for external use).

In some embodiments, the process 900 reuses the same weights for multiple neural network computing operations (e.g., to process multiple different inputs). In such embodiments, the process 900 can return to block 906 to read a second set of inputs from the memory dies, without reprogramming the weights into the functional die(s), then executes a second neural network computing operation at block 908. Stated another way, once the functional die(s) have been programmed with the relevant weights for a neural network computing operation, the process 900 can run iteratively through blocks 906, 908 for multiple different input vectors. In a specific, non-limiting example, as a result, the process can run a face detection neural network computing operation on multiple different images without needing to reprogram the functional die(s).

FIG. 10 is a flow diagram of a process 1000 for programming threshold voltages at one or more memory cells on a flash memory device in accordance with some embodiments of the present technology. The process 1000 can be executed, for example, by one or more controllers on an interface die (e.g., the interface die 332 of FIG. 3; the interface die 410 of FIG. 4; and/or the interface die 510 of FIG. 5A). As a result, the process 1000 can be completed fully within the function HBM device to reduce the power and time needed for and/or to reduce the heat generated by the process 1000. The process 1000 can be performed to program the threshold voltages of the one or more memory cells based on corresponding weights used in one or more neural network computations. For example, the process 1000 may be performed as part of the process 900 illustrated in FIG. 9 (e.g., as part of block 904 of the process 900), to program the one or more memory cells coupled to a word line (e.g., within a row). The one or more memory cells may be of the type discussed above with reference to FIG. 8. Accordingly, the process 1000 FIG. 10 is discussed below with reference to FIG. 8 for the purpose of illustration. However, one of skill in the art will understand that the process 1000 can be executed to program threshold voltages in various other flash memory devices.

The process 1000 begins at block 1002 by selecting a row to program, such as the first row 810 of FIG. 8. In some embodiments, the process 1000 selects multiple rows at block 1002 to program the same weights into multiple selected rows (e.g., to provide one or more backup rows, to be able to average outputs from rows to account for minor variations in the processes 900, 1000, and/or the like). Similarly, at block 1004, the process selects a memory cell on the selected row to program, such as the first-first flash memory cell 812₁ of FIG. 8.

At block 1006, the process 1000 includes setting a word line voltage (e.g., V_{gs1} of the first word line 802₁ FIG. 8) for the word line of the selected row to a first voltage based on the weight. More specifically, the first voltage can be based on the desired weight for the first-first flash memory cell 812₁ (FIG. 8), as well as various process-related constants (e.g., losses when programming the threshold voltage). As discussed above, the programming is completed to set the first-first threshold voltage Vₜₕ₁₁ such that the result of k*(V_{gs1}−Vₜₕ₁₁) is equal to the weight, where V_{gs1} is a constant word line voltage that will be applied to the word line during the neural network computing operation.

At block 1008, the process includes setting a bit line voltage on a bit line coupled to the selected memory cell (e.g., first-first flash memory cell 812₁ of FIG. 8) to a second voltage. The second voltage can be zero (or a about zero) and/or a negative value to create a voltage difference across the selected memory cell that is large enough to program the threshold voltage. At block 1010, the process 1000 includes setting the bit line voltage for each other bit line coupled to each other memory cell (e.g., the second-nth first flash memory cells 812₂₋ₙ of FIG. 8) on the word line of the selected row to a third voltage based on the weight and/or the first voltage. That is, the third voltage should be sufficiently similar to (or equal to) the first voltage, which as described above is set based on a weight, so as to avoid affecting the threshold voltage at each of the other memory cells (i.e., such that the other memory cells are not activated and/or programmed). Returning to the example above, the first bit line voltage V_{bl1} for the first bit line 804₁ of FIG. 8 would be set to zero (or a negative value) at block 1008, and at block 1010 the second-nth bit line voltages V_{bl2-n} would be set to the same (or about the same) voltage set for V_{gs1} at block 1006. It will be understood that, in some embodiments, blocks 1008 and 1010 are executed simultaneously (or generally simultaneously) to set each of the bit line voltages at one time. In some embodiments, block 1010 is executed before block 1006 (e.g., generally simultaneously with block 1004 or immediately after block 1004) to set the bit line voltages for non-targeted memory cells to the target voltage before setting the bit line voltage for the first memory cell.

After each of the bit line voltages have been set, at block 1010, the process 1000 includes programming the selected memory cell at block 1012. Programming the selected memory cell can include applying the set voltages (if not already applied) to the word line and bit lines. Once applied, each of the memory cells in the selected row will see a voltage difference between the word line voltage and the bit-line voltage. For the selected memory cell (e.g., the first-first flash memory cell 812₁ of FIG. 8), the voltage difference is equal (or generally equal) to the first voltage (or the first voltage minus the second voltage). As a result, the voltage difference will program the first voltage as the desired threshold voltage at the selected memory cell (e.g., setting the first-first threshold voltage Vₜₕ₁₁). At each of the other, non-targeted memory cells (e.g., the second-nth first flash memory cells 812₂₋ₙ of FIG. 8), there is no voltage difference (or almost no voltage difference). As a result, the process 1000 does not change the threshold voltage at any of the other memory cells (i.e., does not program them). In some embodiments, block 1012 is executed simultaneously (or generally simultaneously) with block 1006 to set and apply the word line voltage V_{gs1} to the word line after setting the bit line voltages V_{bl} for each of the bit lines at blocks 1008 and 1010.

At decision block 1014, the process 1000 checks whether the selected memory cell was the last memory cell on the word line of the selected row needing to be programmed. If the selected memory cell was the last memory cell, the process 1000 moves on to decision block 1014, else the process 1000 returns to block 1004 to select the next memory cell on the word line in the selected row and program the threshold voltage at the next memory cell. For example, the process 1000 can set the word line voltage V_{gs} to a first voltage based on the weight intended for the second memory cell (e.g., second-first flash memory cell 812₂ of FIG. 8); set the second bit line voltage V_{bl2} to a second voltage (e.g., zero); set the first and third-nth bit line voltages V_{bl1, 3-n} to a third voltage (e.g., equal to or generally equal to the first voltage); and apply the word line voltage V_{gs1} to the word line to program the second-first threshold voltage Vₜₕ₁₂. The process 1000 can then continue to cycle through blocks 1004-1012 to sequentially program the voltage for each of the third-nth memory cells in the selected row.

At decision block 1016, the process 1000 checks whether the selected row was the last row on the memory device needing to be programmed. If the selected row was the last row, the process 1000 moves on to block 1018 to complete, else the process 1000 returns to block 1002 to select the next row. The process 1000 can then cycle through blocks 1004-1014 to program the voltage for each of the memory cells in the new selected row before returning to decision block 1016 to continue selecting rows until each row has been programmed.

At block 1018, the process 1000 ends the programming with the threshold voltage for each of the memory cells set to a desired value. In some embodiments, the process 1000 at block 1018 includes setting the word line voltage V_{gs} for each row to a predetermined constant (e.g., several voltages, tens of volts, and/or the like) to prepare each of the word lines for neural network computing operations. In some embodiments, the process 1000 at block 1018 returns a completion signal (e.g., to a component in the interface die), allowing another process (e.g., the process 900 of FIG. 9) to move forward with neural network computing operations.

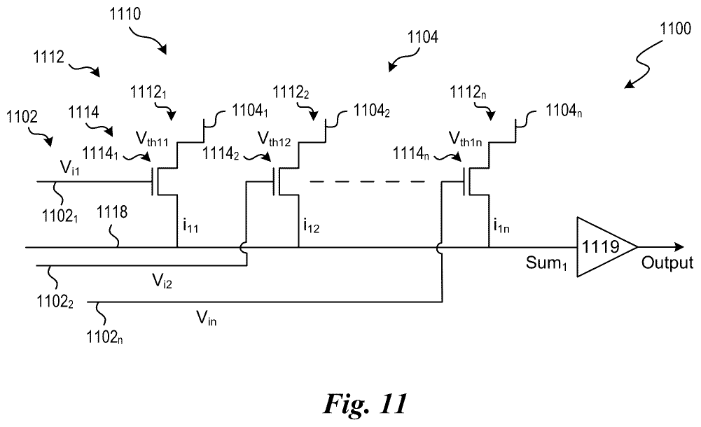

FIG. 11 is a partially schematic circuit diagram of a flash memory device 1100 configured in accordance with further embodiments of the present technology. In the illustrated embodiment, the flash memory device 1100 includes a row 1110 that includes a plurality of flash memory cells 1112 (n-number of flash memory cells illustrated schematically). The flash memory cells 1112 illustrated in FIG. 11 are generally similar to the first flash memory cells 812 discussed above with reference to FIG. 8. For example, a first flash memory cell 1112₁ includes a drain terminal coupled to a first bit line 1104₁, a first threshold voltage 1114₁, and a source terminal coupled to a source line 1118; a second flash memory cell 1112₂ includes a drain terminal coupled to a second bit line 1104₂, a second threshold voltage 1114₂, and a source terminal coupled to the source line 1118; and so on to an nth flash memory cell 1112, that includes a drain terminal coupled to an nth bit line 1104ₙ, an nth threshold voltage 1114ₙ, and a source terminal coupled to the source line 1118. Further, each of the flash memory cells 1112 shares the source line 1118, and each outputs a current to the source line 1118 in an additive manner (e.g., the source line 1118 sums the output currents from the flash memory cells 1112). The source line 1118 then passes through a filter circuit 1119 that acts as an activation function for the row 1110.

In the illustrated embodiment, however, each of the flash memory cells 1112 in the row 1110 is coupled to an independent word line 1102. For example, the first flash memory cell 1112₁ includes a gate terminal coupled to a first word line 1102₁ to apply a first word line voltage V_{gs1} to the first flash memory cell 1112₁; the second flash memory cell 1112₂ includes a gate terminal coupled to a second word line 11022 to apply a second word line voltage V_{gs2} to the second flash memory cell 1112₂; and so on to the nth flash memory cell 1112ₙ includes a gate terminal coupled to an nth word line 1102ₙ to apply an nth word line voltage V_{gsn} to the nth flash memory cell 1112ₙ. Said another way, the flash memory device 1100 includes a plurality of word lines 1102 individually coupled to a corresponding one of the flash memory cells 1112 in the row 1110. While the illustrated embodiment can require a larger footprint for the row 1110 (e.g., as compared to the first row 810 of FIG. 8) to accommodate the plurality of word lines 1102, the independent word line for each of the flash memory cells 1112 can accelerate various operations of the flash memory device 1100.

For example, since each of the flash memory cells 1112 includes an independent word and bit line 1102, 1104, each of the thresholds 1114 (e.g., the first-nth thresholds 1114₁₋ₙ) can be programmed with a threshold voltage Vₜₕ simultaneously (or generally simultaneously). More specifically, a programming process (e.g., implemented by an interface die) can set each word line voltage V_{gs1-n} to a target voltage at a corresponding one of the flash memory cells 1112; set each bit line voltage V_{bl1-n} to zero; and apply the first-nth word line voltages V_{gs1-n} to the first-nth word lines 1102₁₋ₙ. Said another way, the programming process for the flash memory device 1100 illustrated in FIG. 11 can program each of the thresholds 1114 in one pass, rather than requiring iterations through blocks 1002-1008 in the process 1000. As a result, the programming process can complete more quickly (e.g., as compared to the process 1000 as applied to a flash memory device of the type illustrated in FIG. 8) and therefore help accelerate a neural network computing operation.

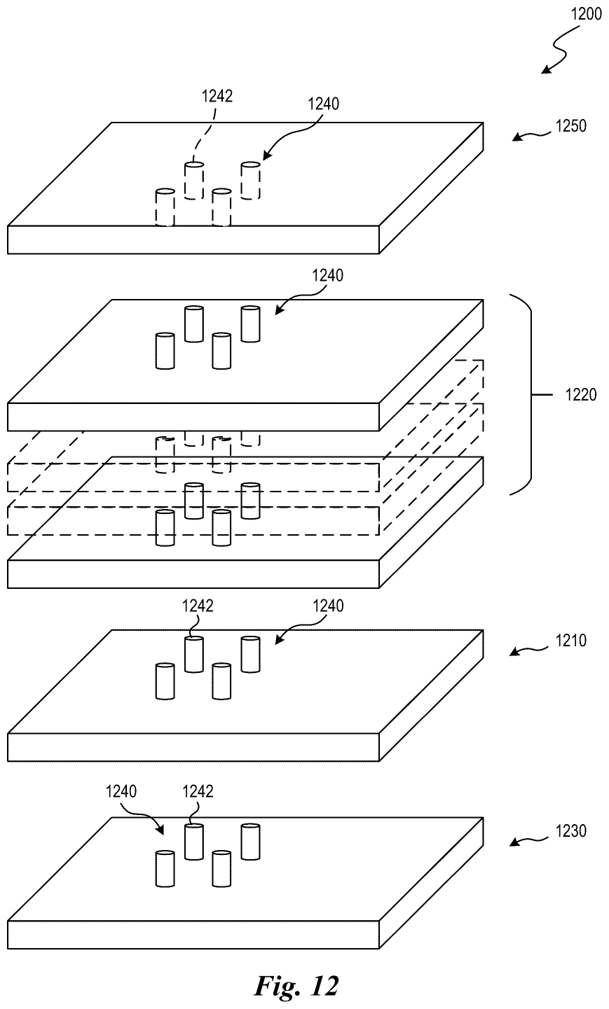

FIG. 12 is a partially schematic exploded view of a functional HBM device 1200 configured in accordance with further embodiments of the present technology. As illustrated in FIG. 12, the functional HBM device 1200 is generally similar to the functional HBM device 400 discussed above with reference to FIG. 4. For example, the functional HBM device 1200 includes an interface die 1210, one or more volatile memory dies 1220 (four illustrated in FIG. 12), and one or more functional dies 1230 (one illustrated in FIG. 12). The functional HBM device 1200 also includes a shared HBM bus 1240 with a plurality of TSVs 1242 communicatively extending between and coupled to the interface die 1210, the volatile memory dies 1220, and the functional die 1230.

In the illustrated embodiment, however, the functional die 1230 can be positioned beneath the interface die 1210. This positioning can reduce (or minimize) the distance between the interface die 1210 and the functional die 1230 to accelerate control signals therebetween (e.g., thereby accelerating the process 1000 discussed above with reference to FIG. 10). However, it will be understood that, in various other embodiments, the functional die 1230 can be positioned in any suitable location in the functional HBM device 1200 (e.g., immediately above the interface die 1210 and/or any other suitable location).

As further illustrated in FIG. 12, the functional HBM device 1200 can also include one or more additional dies 1250 (one illustrated in FIG. 12). The additional die 1250 can include a static random-access memory (SRAM) die (e.g., providing a cache to the functional HBM device 1200 supporting computational operations thereon, acting as an L3 (or higher) cache, and/or the like), a controller die or other suitable processing unit, a non-volatile memory die, a logic die, and/or any other suitable component.

In a specific, non-limiting example, the additional die 1250 can be a non-volatile memory die, such as a NAND memory die. The non-volatile memory die can provide a relatively large memory capacity that is “closer” to the functional die 1230 and/or the volatile memory dies 1220 (e.g., accessible within the functional HBM device 1200 through the relatively high bandwidth of the shared HBM bus 1240) as compared to an off-SiP storage device (e.g., the storage device 240 discussed above with reference to FIG. 2). As a result, for example, a relatively large dataset can be communicated from the off-SiP storage device to the non-volatile memory die to be used during a processing operation (e.g., various trained weight vectors for neural network computing operations, large input datasets for neural network computing operations, and/or the like). The functional HBM device 1200 can then iteratively communicate subsets of the data to the volatile memory dies 1220 to be accessed, used, and/or processed in the functional die 1230.

### CONCLUSION

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A method for operating a high bandwidth memory (HBM) device, the method comprising:
reading a plurality of weights for a trained neural network from one or more memory dies in the HBM device;
programming a threshold voltage for each of a plurality of memory cells on a flash memory die in the HBM device based on the plurality of weights for the trained neural network;
reading a plurality of inputs for a neural network computing operation from the one or more memory dies in the HBM device; and
executing the neural network computing operation using the plurality of inputs.

2. The method of claim 1 wherein programming the threshold voltage for each of the plurality of memory cells comprises, for a first memory cell in plurality of memory cells coupled to a word line of the flash memory die:
setting a word line voltage for the word line to a first voltage based on a first weight from the plurality of weights;
setting a first bit line coupled to the first memory cell to a second voltage different from the first voltage; and
for each other memory cell from the plurality of memory cells on the word line, setting a corresponding bit line to the first voltage.

3. The method of claim 2 wherein programming the threshold voltage for each of the plurality of memory cells further comprises, for a second memory cell in the plurality of memory cells:
setting the word line voltage to a third voltage based on a second weight from the plurality of weights;
setting a second bit line coupled to the second memory cell to a fourth voltage different from the third voltage; and
for each other memory cell from the plurality of memory cells on the word line, setting the corresponding bit line to the third voltage.

4. The method of claim 2 wherein the word line is a first word line of a plurality of word lines, wherein the word line voltage is a first word line voltage, wherein the plurality of memory cells is a plurality of first memory cells, and wherein programming the threshold voltage for the plurality of memory cells further comprises, for a second memory cell from a plurality of second memory cells coupled to a second word line:
setting a second word line voltage for the second word line to a third voltage based on a second weight from the plurality of weights;
setting a second bit line coupled to the second memory cell to a fourth voltage different from the third voltage; and
for each other memory cell from the plurality of second memory cells, setting a corresponding bit line to the third voltage.

5. The method of claim 1 wherein:
the flash memory die includes a plurality of word lines, a plurality of bit lines, and a plurality of source lines, wherein each of the plurality of word lines is coupled to two or more memory cells from the plurality of memory cells, and wherein each of the two or more memory cells is coupled to one of the plurality of bit lines and outputs to a common source line from the plurality of source lines; and
executing the neural network computing operation using the plurality of inputs comprises:
loading a bit line voltage to each of the plurality of bit lines based on an individual value from the plurality of inputs;
applying a filter to a resulting current on each source line of the plurality of source lines; and
reading an output from each of the plurality of source lines.

6. The method of claim 5 wherein the output of each source line from the plurality of source lines is based on a sum of output currents from the two or more memory cells.

7. The method of claim 1 wherein the neural network computing operation is a first neural network computing operation and the plurality of inputs are a first plurality of inputs, and wherein the method further comprises:
reading a second a plurality of inputs for a second neural network computing operation from the one or more memory dies in the HBM device; and
executing a second neural network computing operation using the second plurality of inputs.

8. The method of claim 1 wherein each memory cell from the plurality of memory cells is individually coupled to a word line from a plurality of word lines and a bit line from a plurality of bit lines, and wherein programming the threshold voltage for the plurality of memory cells comprises, for each individual memory cell in the plurality of memory cells:
setting a word line voltage for a corresponding word line from the plurality of word lines to a first voltage based on a corresponding weight from the plurality of weights; and
setting a corresponding bit line coupled to the individual memory cell to a second voltage different from the first voltage.

9. The method of claim 1, further comprising writing, from a storage die peripheral to the HBM device, the plurality of weights for the trained neural network and the plurality of inputs for the neural network computing operation into the one or more memory dies.

10. A functional high bandwidth memory (HBM) device, comprising:
a controller die;
one or more volatile memory dies carried by the controller die;
a flash memory die carried by the one or more volatile memory dies, the flash memory die comprising:
one or more rows each having a word line and two or more programmable memory cells coupled to the word line; and
two or more bit lines, wherein each of the two or more bit lines is coupled to a corresponding programmable memory cell from each of the one or more rows; and
a shared bus electrically coupled to each of the controller die, the one or more volatile memory dies, and the flash memory die,
wherein the controller die is configured to control the one or more volatile memory dies and the flash memory die, through the shared bus, to implement one or more neural network computing operations within the functional HBM device.

11. The functional HBM device of claim 10 wherein implementing the one or more neural network computing operations comprises:
reading a plurality of weights for a trained neural network from one or more volatile memory dies;
programming a threshold voltage for each of the two or more programmable memory cells in each of the one or more rows in the flash memory die based on the plurality of weights for the trained neural network;
reading a plurality of inputs for the one or more neural network computing operations from the one or more volatile memory dies; and
executing the one or more neural network computing operations on the two or more programmable memory cells in each of the one or more rows using the plurality of inputs.

12. The functional HBM device of claim 11 wherein programming the threshold voltage for a first individual programmable memory cell of the two or more programmable memory cells in a first row comprises:
setting a word line voltage for a first word line in the first row to a first voltage based on a first weight from the plurality of weights;
setting a bit line coupled to the first individual programmable memory cell to a second voltage different from the first voltage; and
for each other programable memory cell in the first row, setting a corresponding bit line to a third voltage different from the second voltage.

13. The functional HBM device of claim 12 wherein the second voltage is zero or negative.

14. The functional HBM device of claim 11 wherein executing one of the one or more neural network computing operations using the inputs comprises:
for each individual bit line from the two or more bit lines, applying a bit line voltage to the individual bit line based on an individual value from the plurality of inputs;
for each individual row, applying an activation function to a current on a source line coupled to each of the two or more programmable memory cells in the individual row; and
reading an output from the activation function.

15. The functional HBM device of claim 14 wherein applying the activation function comprises comparing the current on the source line to a reference current.

16. A system-in-package (SiP) device, comprising:
a base substrate;
a processing unit carried by the base substrate; and
a functional high-bandwidth memory (HBM) device carried by the base substrate and electrically coupled to the processing unit through a SiP bus, wherein the functional HBM device comprises:
a controller die;
one or more memory dies;
a neural network computing die; and
a shared bus electrically coupled to each of the controller die, the one or more memory dies, and the neural network computing die,
wherein the controller die is configured to control the one or more memory dies and the neural network computing die, through the shared bus, to implement one or more neural network computing operations within the functional HBM device.

17. The SiP device of claim 16 wherein the neural network computing die includes a NOR flash array having a plurality of rows, wherein each of the plurality of rows includes a shared word line and a plurality of memory cells communicably coupled to the shared word line, wherein each of the plurality memory cells has a programmable threshold voltage.

18. The SiP device of claim 16 wherein implementing the one or more neural network computing operations comprises:
reading a plurality of weights for the one or more neural network computing operations from one or more memory dies;
writing the plurality of weights into threshold voltages for a plurality of memory cells in the neural network computing die;
reading a plurality of inputs for each of the one or more neural network computing operations from the one or more memory dies; and
executing each of the one or more neural network computing operations.

19. The SiP device of claim 18 wherein writing the plurality of weights into threshold voltages for a plurality of memory cells comprises sequentially programming an individual threshold voltage for each of the plurality of memory cells based on an individual one of the plurality of weights.

20. The SiP device of claim 18 wherein:
the neural network die includes (1) a plurality of word lines each communicably coupled to a subset of the plurality of memory cells, and (2) a plurality of bit lines each coupled to a memory cell on each of the plurality of word lines; and
executing each of the one or more neural network computing operations comprises applying a bit line voltage to each of the plurality of bit lines based on an individual input from the plurality of inputs.
